(19) United States
(12) Patent Application Publication
(10) Pub. No.: US 2010/0327400 A1
(43) Pub. Date: Dec. 30, 2010

(54) FUSE STRUCTURE AND FABRICATION METHOD THEREOF

(75) Inventors: Ki Soo Choi, Goyang (KR); Keon Yoo, Icheon (KR); Mi Hyeon Jo, Jeollanam-do (KR)

Correspondence Address: AMPACC Law Group, PLLC;LOADING..., 6100 219th Street SW, Suite 580, Mountlake Terrace, WA, 98043, US

(73) Assignee: Hynix Semiconductor Inc., Icheon-si (KR)

(21) Appl. No.: 12/648,247

(22) Filed: Dec. 28, 2009

(30) Foreign Application Priority Data
Jun. 30, 2009 (KR) 10-2009-0058723

(51) Int. Cl. H01L 23/525

(52) U.S. Cl. 257/529; 257/E23.149

(57) ABSTRACT

A semiconductor device includes a fuse box including a plurality of fuses and a plurality of common nodes, wherein paired fuses among the plurality of fuses are aligned in a first direction and the plurality of common nodes between fuses of each of the pairs at a different height is aligned in a second direction perpendicular to the first direction.

### CROSS-REFERENCE TO RELATED APPLICATION

The priority based on Korean patent application No. 10-2009-0058723 filed on Jun. 30, 2009, the disclosure of which is hereby incorporated in its entirety by reference, is claimed.

### BACKGROUND OF THE INVENTION

The present invention relates to a semiconductor device, and more specifically, to a fuse included in a high-integrated semiconductor device for determining an electric signal transfer or a connection between different two terminals.

Generally, a fuse is defined as a kind of an automatic cut-off device for preventing an overflowing current from continuously flowing through an electric wire. That is, in case of overflow, the fuse melts itself in order to cut the electric connection using heat generated by an overflow of electricity, i.e., an electric current. Such a fuse can be easily found in our daily lives. The fuse allows the electric current to continuously flow under its normal state; however, once the fuse is cut, the electric connection is permanently severed unless the fuse is replaced. This point differentiates the fuse from a switch capable of temporarily controlling a connection and a disconnection of a flow of the electric current.

A semiconductor device is designed to operate according to an intended purpose through a process of applying impurities into a predetermined region within a silicon wafer or depositing new material. A typical example of the semiconductor device is a semiconductor memory device. The semiconductor memory device includes many elements such as a transistor, a capacitor, a resistor and the like for performing a predetermined purpose; and the fuse is also one of the elements included therein. The fuse is used in many areas within the semiconductor memory device; a redundancy circuit and a power supply circuit are typical examples of them. The fuses are built on the semiconductor chip and connected to such a circuit during fabrication process and then are selectively blown afterwards based on the defect test results in order to isolate the defective components in the chip.

Explanation on how a redundancy circuit works will be followed in detail. In the case that a particular unit cell turns out defective in the semiconductor memory device, the defective unit cell is replaced with a redundant normal cell through a recovery step. That is, an address of the defective unit cell is stored at the recovery step in order to prevent the detective unit cell from being accessed. When an address of the defective unit cell is received, a redundant normal cell instead of the defective unit cell is accessed by the redundancy circuit. The fuse of the redundancy circuit is used for storing the address of the defective unit cell at the recovery step by selectively blowing out the fuse corresponding to the defective unit cell, for example, using a laser within the semiconductor memory device so that an electrical connection to the defective unit cell is permanently cut. This process is referred to as a fuse blowing step.

A semiconductor memory device includes a plurality of unit cells. It is predict how many and where defective unit cells would occur. Therefore, a fuse box including a plurality of fuses is provided within the semiconductor memory device in order to replace defective unit cells with redundant normal cells.

A data storage capacity of the semiconductor memory device continues to increase. With the increase in the number of unit cells provided in a semiconductor device, the number of fuses needs to be increased correspondingly to adequately replace the defective unit cells with redundant normal cells. However, the size of the semiconductor memory device needs to be decreased to obtain a highly integrated semiconductor device. As -mentioned above, a laser is used to selectively blow out a fuse. Adjacent fuses should be spaced apart sufficiently to prevent unintentional blowing out a neighboring fuse during a fuse blowing process. However, this spacing requirement uses up valuable real estate in the semiconductor memory device. It would be desirable to find a technique of preventing accidental blowing of neighboring fuses that does not require large real estate.

FIG. 1 is a block diagram illustrating a fuse included in a conventional semiconductor device. In detail, FIG. 1 shows two fuses coupled to a single common node in a sectional view.

As shown, one side of each of first and second fuses 110 and 120 is connected to a first power supply source through a common node 130 and the other side is connected to a circuit connection unit 140A and 140B. Power supply voltage (VDD) serves as the common node 130 generally, and the circuit connection units 140A and 140B coupled to the other side of each of the first and second fuses 110 and 120 is connected to a bit line generally. Also, the semiconductor device includes a plurality of contacts 150A to 150C for connecting the common node to the one side of each of the first and second fuses 110 and 120 and for connecting the circuit connection unit 140A and 140B to the other side of each of the first and second fuses 110 and 120.

In addition, the semiconductor device further includes first and second guard-ring structures 160 and 170 for protecting internal circuits connected to the first and second fuses 110 and 120 when the first fuse 110 or the second fuse 120 is blown; and a passivation layer 180 for protecting other elements from the blowing process. Herein, in order to facilitate a blowing process performed to the first and second fuses 110 and 120 using a laser or the like, the passivation layer 180 is formed over the first and second fuses 110 and 120 with a less thickness in comparison with the other regions so that a fuse open region 190 is formed over the first and second fuses 110 and 120.

FIG. 2 is a plan view for explaining a defect of the semiconductor device shown in FIG. 1 at the fuse blowing process. Particularly, FIG. 2 shows that a corrosion phenomenon which occurs at a neighboring fuse F4 coupled to a blown fuse F3 through the common node in a fuse box including a plurality of fuses F1 to F6. Herein, the common node and the contacts covered by the passivation layer 180 are not shown in FIG. 2.

The fuses F1 to F6 are connected in pairs with a neighboring fuse as shown in FIG. 1. On the assumption that only a single fuse, i.e., the third fuse F3, should be blown between coupled two fuses, a connection is severed by applying the laser to the fuse open region 190 exposed by the passivation layer 180 at the second and third fuses F2 and F3 as shown in FIG. 2. At this time, since neighboring two fuses, i.e., the third and fourth fuses F3 and F4, which share the common node are formed in a single conductive layer, it is highly likely that heat and energy given to the third fuse F3 at the timing of blowing are transferred to the fourth fuse F4. Particularly, in the case that material which constitutes the third fuse F3 has high conductivity and corrosiveness like a copper (Cu), damage due to the blowing is more easily transferred to the neighboring fourth fuse F4.

For preventing the above-mentioned problem of thermal degradation or the like, such a metal as aluminum, tungsten or the like whose heat conductivity is relatively low in comparison with the copper has been used for manufacturing the fuse. However, in the case of forming the fuse or the wire using these metals, resistance becomes high at a micro-level process, and thus a processing speed may be delayed or a power loss may occur due to current leakage. Since a size of the fuse of the wire should be increased to overcome this problem, the high integration of the semiconductor device is limited consequently. However, as mentioned above, in the case of forming the fuse using the copper, the fuse formation is difficult due to the properties of the copper. Therefore, a new fuse design which is suitable for a high integrated semiconductor memory device is desirable.

### BRIEF SUMMARY OF THE INVENTION

Embodiments of the present invention relate to a semiconductor device capable of improving an operation reliability of a semiconductor device not increasing a size of a fuse by preventing thermal degradation and corrosion generated at a fuse blowing process by physically separating a plurality of fuses included in a fuse box and connecting them to a common node and a circuit connection unit through a contact.

In accordance with an embodiment of the present invention, there is provided a semiconductor device including a fuse box including a plurality of fuses and a plurality of common nodes, wherein paired fuses among the plurality of fuses are aligned in a first direction and the plurality of common nodes between fuses of each of the pairs at a different height is aligned in a second direction perpendicular to the first direction.

The paired fuses are connected to the common node through a different contact and the contact is constituted with conductive material which has different heat conduction characteristics from the fuse. The fuse is constituted with metal material including a copper and the contact is constituted with metal material including one or more of tungsten and tantalum except for the copper.

In another embodiment, the contact is connected to a lower part of end of the fuse in the case that the common node is formed at a lower height than the plurality of fuses. The common node is formed at a same height as a bit line of a circuit unit to which the pair of fuses is respectively coupled.

In another embodiment, the contact is connected to an upper part of end of the fuse in the case that the common node is formed at a higher height than the plurality of fuses. The common node is formed at a substantially same position as a guard-ring structure formed on both ends of the pair of fuses.

The fuse box includes a box-shaped region surrounded by a guard-ring structure and a common wire connecting the plurality of common nodes crosses a center part of the fuse box. The common wire has same height and structure as a bit line of a circuit unit.

The fuse box further includes a passivation layer for protecting the guard-ring and the plurality of fuses, wherein the passivation layer is formed on a blowing region of the plurality of fuses with a lower depth than that of the other regions.

### BRIEF DESCRIPTION OF THE DRAWINGS

FIG. 1 is a block diagram illustrating a conventional fuse included in a semiconductor device.

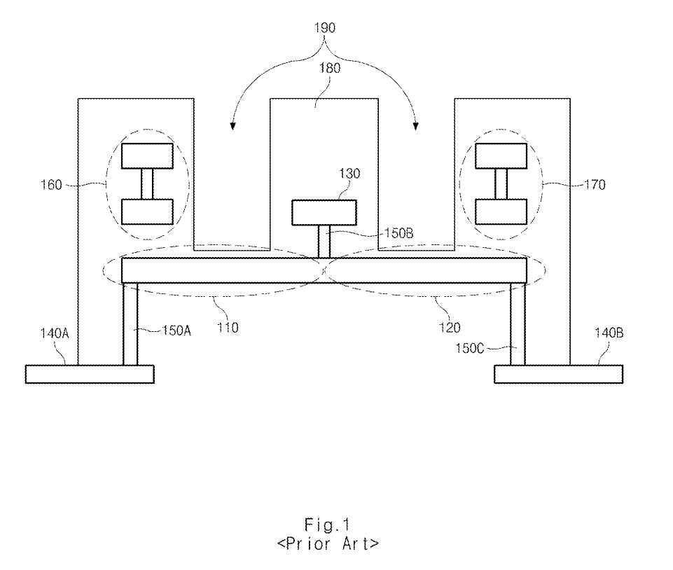

FIG. 2 is a plane view for explaining a defect occurring at a fuse blowing process of the semiconductor device shown in FIG. 1.

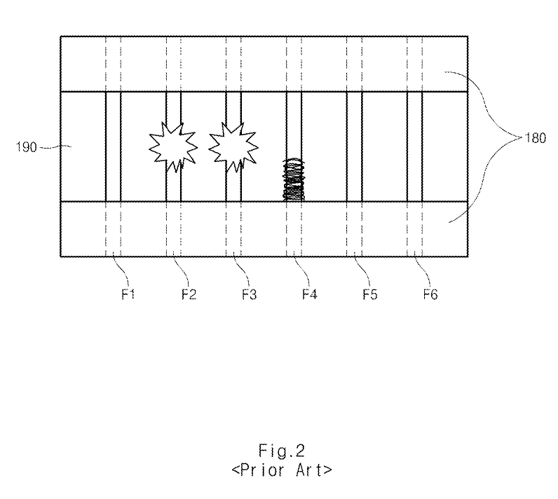

FIG. 3 is a plane view illustrating a fuse included in a semiconductor device in accordance with an embodiment of the present invention.

FIG. 4 is a cross-sectional view illustrating a pair of fuses included in the semiconductor device shown in FIG. 3.

FIG. 5 is a cross-sectional view illustrating a pair of fuses included in a semiconductor device in accordance with another embodiment of the present invention.

### DESCRIPTION OF EMBODIMENTS

The present invention proposes a structure of a fuse capable of preventing a fuse which neighbors with a target fuse to be blown from suffering thermal degradation and safely performing a blowing process even if the fuse is formed using copper.

Hereinafter, preferred embodiments of the present invention are described with reference to the accompanying drawings.

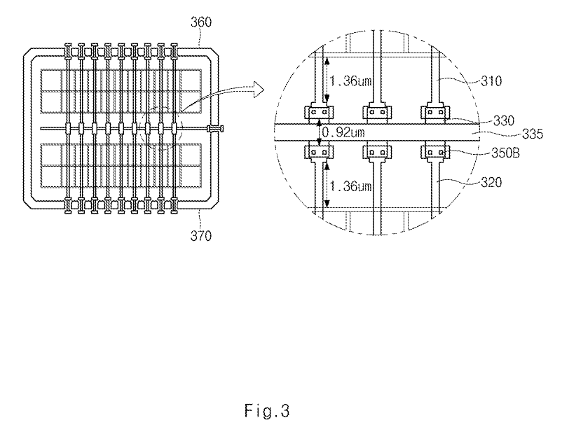

FIG. 3 is a plan view illustrating a fuse included in a semiconductor device in accordance with an embodiment of the present invention.

As shown, a fuse box included in the semiconductor device includes a plurality of fuses in a box-shaped region defined by guard-rings 360 and 370. The fuses are coupled in pairs, and a pair of fuses is aligned in a first direction (e.g., a column direction in FIG. 3). Unlike the prior art, fuses 310 and 320 (comprising a pair) pair are physically separated from each other. A common node 330 is formed between the two fuses 310 and 320, and each of the two fuses 310 and 320 is connected to the common node 330 through a contact 350B, thus being electrically connected to each other. Herein, the two fuses 310 and 320 and the common node 330 can be formed with a step difference. Although it is shown in FIG. 3 that there is a distance of about 0.92 μm between the two fuses 310 and 320 aligned in a perpendicular direction, this numerical value is just an example of the embodiment and may be a different value. One factor to consider is that a minimum distance should be secured so that heat conduction does not directly occur between the two fuses aligned in a perpendicular direction.

In addition, a plurality of common nodes 330 formed between each ear of the fuses 310 and 320 is aligned in a second direction (e.g., a row direction in FIG. 3) different from the first direction, e.g., perpendicular to the first direction, and is connected together through a common wire 335. The common wire 335 may position so as to pass across a center part of the fuse box and is generally connected to a ground voltage. Meanwhile, the common wire 335 in accordance with the embodiment of the present invention can be formed to have the same height and structure as a bit line formed at a cell region of the semiconductor device.

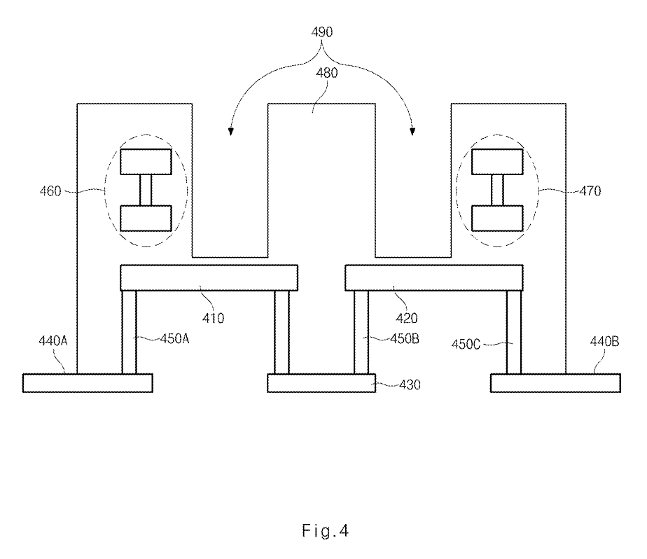

FIG. 4 is a cross-sectional view illustrating the pair of fuses included in the semiconductor device shown in FIG. 3.

As shown, a pair of fuses 410 and 420 is not formed of a single line-shaped pattern but is spaced apart from each other unlike the prior art. A common node 430 connected to the two fuses 410 and 420 is formed between the two fuses 410 and 420. Herein, the common node 430 is formed at a position lower than the two fuses 410 and 420 with a step difference.

In the case that the common node 430 is formed at a lower position than the two fuses 410 and 420, the common node 430 is formed, a contact 450B is formed thereon, and the two fuses 410 and 420 are formed on an upper part of the contact 450B. Particularly, after forming a line-shaped fuse pattern (not shown), a center part of the fuse pattern is removed to separate the fuse pattern into the two fuses 410 and 420. The common node 430 can be formed at substantially the same level as a bit line of circuit units 440A and 440B.

The two fuses 410 and 420 can be formed of metal material including a copper (Cu), and the contact 450B is formed of material having a lower heat conductivity than that used the two fuses 410 and 420, for example, tungsten, tantalum or the like. This is to reduce the heat transfer between the two fuses 410 and 420 so that only the selected fuse is blown without damaging the other fuse. Unlike the prior art, in accordance with the present invention, since a pair of fuses 410 and 420 are not directly coupled together but indirectly coupled together through the contact 450B formed of different material from the fuses 410 and 420, even if the blowing process is performed to one of the pair of the fuses 410 and 420, the other fuse can be prevented from suffering thermal degradation.

In one embodiment, the fuses 410 and 420 and the common node 430 may be formed of the same material; however, the contact 450B is formed of material having less heat conductivity. In another embodiment, the fuses 410 and 420, the common node 430, and the contact 450B are formed of substantially the same material; however the contact 450B is made to extend vertically sufficiently high to increase the heat transfer path between the two fuses.

Meanwhile, the semiconductor device of the present invention includes contacts 450A and 450C for respectively connecting the fuses 410 and 420 with the circuit units 440A and 440B; guard-rings 460 and 470 positioned at one end of each fuse 410, 420, respectively; and a passivation layer 480 for protecting the guard-rings 460 and 470 and the pair of fuses 410 and 420. The passivation layer 480 is formed over the pair of fuses 410 and 420 and defines a fuse open region 490. The passivation layer 480 has a less thickness at the fuse open region 490 (or fuse blowing region) to enable the fuse to be blown there.

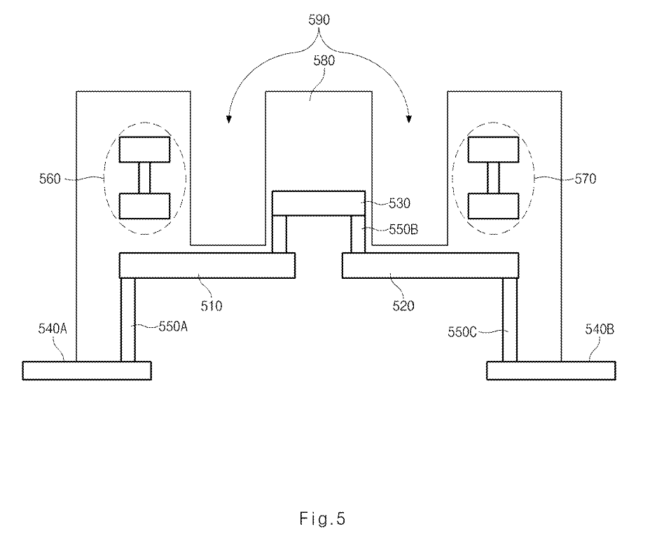

FIG. 5 is a cross-sectional view illustrating a pair of fuses included in a semiconductor device in accordance with another embodiment of the present invention.

As shown, a pair of fuses 510 and 520 included in the semiconductor device in accordance with the other embodiment of the present invention is not formed of a single line but formed of physically separated bodies, like the pair of fuses 410 and 420 shown in FIG. 4. However there is a difference in that a common node 530 coupled to the two fuses 510 and 520 is not formed at a lower position than the two fuses 510 and 520 but formed at a higher position than the two fuses 510 and 520.

In the case that the common node 530 is formed at a higher position than the two fuses 510 and 520, a line-shaped fuse pattern (not shown) is formed, and a center part of the fuse pattern is removed so that the fuse pattern is separated into the two fuses 510 and 520. Thereafter, a contact 550B is formed on the two fuses 510 and 520 and the common node 530 is formed on the contact 550 Bover the place where the removed center part was originally located. The common node 530 can be formed with a substantially same height as the two guard-rings 560 and 570 for protecting an internal circuit from damages when any of the two fuses 510 and 520 is subject to blowing.

Besides, a fuse box in accordance with the other embodiment of the present invention includes a passivation layer 580 for protecting the guard-rings 560 and 570, the common node 530 and the pair of fuses 510 and 520. Herein, the passivation layer 580 is formed over the pair of fuses 510 and 520 with a lower depth than that of the other regions, forming a fuse open region 590 (i.e., a fuse blowing region). Like the embodiment shown in FIG. 4, since a pair of two neighboring fuses 510 and 520 are not directly coupled together but indirectly coupled together through the contact 550B formed of a different material from the fuses 510 and 520, even if the blowing process is performed to one of the pair of the fuses 510 and 520, the other fuse can be protected from thermal degradation.

According to the prior art, a neighboring pair of fuses are directly coupled together so that thermal degradation occurs when one of the fuses is severed from a connection through the blowing process; however, in accordance with the present invention, even if one the neighboring fuses is severed through the blowing process and suffers thermal degradation, this thermal degradation is not transferred to the other fuse. The degree of thermal degradation of the fuse is determined according to energy of the laser applied at the blowing process. According to the prior art, fuses were formed with a longer interval to protect the neighboring fuse from being damaged due to heat conductivity. However, in accordance with the present invention, since each fuse is electrically connected to each other but not physically coupled together, the fuses may be formed more compact.

Therefore, in accordance with the present invention, since the fuse included in a high integrated semiconductor device becomes free from the thermal degradation at the blowing process by physically separating each fuse forming one pair and connecting the fuse to the common node through the contact formed of conductive material of different material characteristics, a size of the fuse box can be maintained small and a resistance of the fuse can be maintained low as well. Accordingly, operational stability can be secured.

Also, in accordance with the present invention, the area for the fuse box can maintained as substantially same size as that of the prior art with preventing the thermal degradation generated at the blowing process, and thus the fuse structure of the present invention can be usefully applied to the high integrated semiconductor.

Further, in accordance with present invention, even if the fuse is formed of the copper, the thermal degradation or the corrosion generated at the blowing process can be prevented and thus the fuse can have a low resistance value. Accordingly, a processing speed delay or power loss due to current leakage can be prevented.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A semiconductor device having a fuse box, the fuse box comprising:
a plurality of fuse pairs, each fuse pair having first and second fuses that are aligned to each other in a first direction; and
a plurality of common nodes provided at a different height than the fuse pairs, each common node being configured to electrically couple the first and second fuses in the fuse pair, the plurality of common nodes being aligned in a second direction that is different from the first direction.

2. The fuse box according to claim 1, wherein the fuses includes a first conductive material, the fuse box further comprising:
a plurality of contacts coupling the fuses to the common nodes, the contacts including a second conductive material that has different heat conduction characteristics than the first conductive material.

3. The fuse box according to claim 2, wherein the first conductive material is copper and the second conductive material is tungsten or tantalum.

4. The fuse box according to claim 2, wherein the common node is provided at a lower height than the fuses.

5. The fuse box according to claim 4, wherein the common node is formed substantially at the same height as a bit line of a circuit unit to which the fuse box is coupled.

6. The fuse box according to claim 2, wherein the common node is provided at a higher height than the fuses.

7. The fuse box according to claim 6, further comprising:
a guard-ring structure defining an outer perimeter of the fuse box,
wherein the common node is formed at substantially the same position as the guard-ring structure.

8. The fuse box according to claim 1, further comprising:
a guard-ring structure defining an outer perimeter of the fuse box,
a common wire extending along the second direction and coupling the plurality of common nodes, the common wire being provided at a midsection of the fuse box.

9. The fuse box according to claim 8, wherein the common wire has substantially the same height and structure as a bit line of the semiconductor device.

10. The fuse box according to claim 1, further comprising:
a passivation layer configured to protect the guard-ring and the plurality of fuses, the passivation layer defining a blowing region of the plurality of fuses.

11. A semiconductor device having a fuse box, the fuse box comprising:
a plurality of fuse pairs provided at a first height, each fuse pair including a first fuse and a second fuse that are spaced apart from each other; and
a plurality of common nodes provided at a second height different from the first height, each common node being configured to electrically couple the first and second fuses in the fuse pair.

12. A semiconductor device having a fuse box, the fuse box comprising:
a plurality of fuse sets provided at a first height, each fuse set including a first fuse and a second fuse that are spaced apart from each other; and
a plurality of common nodes provided at a second height different from the first height, each common node being configured to electrically couple the first and second fuses in the fuse set.

13. The fuse box of claim 12, wherein the first and second fuses are aligned to each other in a first direction, and the common nodes are aligned to each other in a second direction that is different from the first direction.

14. The fuse box of claim 12, further comprising:
a plurality of contacts coupling the common nodes to the fuses.

15. The fuse box of claim 14, wherein the fuses includes a first conductive material, the common nodes includes a second conductive material, the contacts includes a third conductive material,
wherein the first conductive material is different than the second conductive material.

16. The fuse box of claim 14, wherein the fuses includes a first conductive material, the common nodes includes a second conductive material, the contacts includes a third conductive material,
wherein the first conductive material is different than the third conductive material.

17. The fuse box of claim 14, wherein the fuses includes a first conductive material, the common nodes includes a second conductive material, the contacts includes a third conductive material,
wherein the first conductive material and the second conductive material are the same material.
